(19) United States
(12) Patent Application Publication
(10) Pub. No.: US 2026/0276683 A1
(43) Pub. Date: Sep. 17, 2026

(54) SENSOR DEVICE AND METHOD FOR NON-INVASIVE MONITORING OF ENERGY CONSUMPTION USAGE

(71) Applicant: Tim Suleymanov, Foster City, CA (US)

(72) Inventor: Tim Suleymanov, Foster City, CA (US)

(21) Appl. No.: 19/574,367

(22) Filed: Mar. 22, 2026

Related U.S. Application Data
(63) Continuation-in-part of application No. 17/717,062, filed on Apr. 9, 2022, now abandoned.

(51) Int. Cl. G01R 21/10; G01B 7/32; G01R 11/04; G01R 35/04; G08B 31/00; H02J 13/12; H02J 13/13; H02J 50/00

(52) U.S. Cl. CPC G01R 21/10; G01B 7/32; G01R 11/04; G01R 35/04; G08B 31/00; H02J 13/12; H02J 13/1335; H02J 50/001

(57) ABSTRACT

A sensor device for non-invasive monitoring of energy consumption usage attached to a power cable. The sensor includes a housing having a bottom part and a top part each presenting end sides and side walls, a controller having a software located inside said housing. A pair of clamping elements pivotably connected to the side walls of the bottom part. Each of the clamping elements including a base presenting a base surface and extending to a clamping surface defining an angle of up to 90 degrees between the base surface and the clamping surface to fixedly attached to the power cables of various cross sections.

### FIELD OF INVENTION

The present invention relates generally to systems and methods of obtaining data about power consumption from industrial equipment.

### BRIEF DESCRIPTION OF THE INVENTION

In the modern world it is absolutely impossible to go without productions of any types, whether it is the manufacture of electronics or food. Unfortunately, the cost of energy resources is constantly growing and every year it takes an increasing percentage of the cost of production.

There is a huge number of manufacturers of production equipment on the market and unfortunately there is no single standard for data exchange between them, as well as the user's software. In this regard, it is not possible to remotely monitor the power consumption of each individual machine or piece of equipment. The problem become more complicated because due to the safety issues, it is dangerous to interfere with the operation of the machine and use any invasive methods for measuring power consumption while the machine is working.

Prior art is replete with various systems for managing energy consumption of different devices. One of the prior art references teaches a system for managing energy of a plurality of devices associated with an enclosure. The energy usage of the devices is monitored. An energy usage rule and energy usage is then compared. The energy management policy and energy usage is also compared. Based on the comparing, an instruction is generated to modify an energy usage profile of the device to correlate with the energy usage rule associated with the devices and the energy management policy, thereby enabling efficient energy management.

Another prior art reference teaches a monitoring system for monitoring the parameters of a machine The monitoring system for monitoring the parameters of a machine includes a power supply unit for supplying electric power to the components of the machine, a control unit of the machine for controlling the operating conditions of the components of the machine, and a measurement network adapted to measure the energy consumptions of the components of the machine and of the power supply unit. The monitoring system further includes a processing unit connected to the measurement network for receiving information about the energy consumptions and connected to the control unit for receiving information about the operating conditions of the components of the machine. The processing unit is adapted to synchronize the energy consumptions of the components of the machine with the operating conditions that caused the energy consumptions.

Still another prior art reference teaches a system and method for monitoring and control of appliances. The system comprises a computer server system and an electronic interface device installed remotely from the computer server system and in wireless communication with the computer server system. The interface device is configured to monitor power consumption of the at least one appliance and to control supply of power to the at least one appliance. The interface device is further configured to periodically transmit monitored power usage data to the computer server system, to receive at least one of data and commands from the computer server system and to control power to the at least one appliance based on the received at least one of data and commands.

Unfortunately, these prior art design present numerous disadvantages including and not limited to redundant parts count that makes its hard to assemble/disassemble. There is always a need for an improved device that is easy to assemble/disassemble and manufacture.

There is also a constant need for a system that would allow measuring power consumption of machines by a non-invasive method with the subsequent transfer of data to the server.

### SUMMARY OF THE INVENTION

A sensor device for non-invasive monitoring of energy consumption usage attached to a surface, such as a power cable. The sensor device includes a housing having a bottom part and a top part each presenting end sides and side walls, and a central axis bisecting the housing. A controller has a sensor element and a software and are located inside the housing. A pair of clamping elements are pivotably connected to the side walls of the bottom part, wherein each of the clamping elements includes a base presenting a base surface and extending to a clamping surface defining an angle of up to 90 degrees between the base surface and the clamping surface.

A clamping mechanism is connected to the clamping elements thereby allowing the clamping elements to pivotably move about the bottom part to move the base surfaces of the clamping elements to and away from the central axis to fixedly attach the sensor device to the power cables of various cross sections as the sensor determines physical data of the power cable and stores the physical data in the controller.

An alternative embodiment of the present invention includes a sensor device for non-invasive monitoring of energy consumption usage attached to a surface, such as a power cable, presenting a housing having a bottom part and a top part each presenting end sides and side walls, and a central axis bisecting said housing, a controller having a sensor element and a software located inside the housing. The sensor device includes a pair of clamping elements pivotably connected to the side walls of the bottom part, each of the clamping elements includes a base presenting a base surface and extending to a clamping surface defining an angle of up to 90 degrees between the base surface and the clamping surface.

The sensor device includes a clamping mechanism connected to the pair of clamping elements thereby allowing the pair of clamping elements to pivotably move about the bottom part to move the base surfaces of the clamping elements to and away from the central axis to fixedly attach the sensor device to the power cables of various cross sections as the sensor determines physical data of the power cable and stores the physical data in said controller.

The clamping surface of each respective clamping elements includes side gripping elements semi-circled by respective ear layers and defining an inlet portion therebetween to receive a first connector element presenting a grip portion, a female tubular member to receive a male tubular member of a second connector element further defining a second grip portion. A flange portion extends from the base of one of the clamping elements. The flange portion includes a female connector to receive a male connector extending from the bottom part to engage with the female connector when the sensor device if secured to the power cable.

An advantage of the present invention is to provide a device that is compact in design.

Another advantage of the present invention is to provide an inventive system that would allow measuring power consumption of machines by a non-invasive method with the subsequent transfer of data to the server.

### BRIEF DESCRIPTION OF THE DRAWINGS

Other advantages of the present invention will be readily appreciated as the same becomes better understood by reference to the following detailed description when considered in connection with the accompanying drawings wherein:

FIG. 1 illustrates a perspective view of a device for non-invasive monitoring of energy consumption usage of the present invention taken from a back.

FIG. 2 illustrates a perspective view of the device of the present invention taken from a front.

FIG. 3 illustrates a back side of the device of the present invention.

FIG. 4 illustrates a front side of the device of the present invention.

FIG. 5 illustrates a top view of the device of the present invention.

FIG. 6 illustrates a side view of the device of the present invention.

FIG. 7 illustrates a cross sectional view of the device that shows all hardware components.

FIG. 8 illustrates a general view of a system.

### DETAILED DESCRIPTION OF THE INVENTION

Referring to description of the present invention, the words “inner”, “inwardly” and “outer”, “outwardly” refer to directions toward and away from, respectively, a designated centerline or a geometric center of an element being described, the particular meaning being readily apparent from the context of the description. Additionally, as used herein, the singular forms “a,” “an,” and “the” include plural referents unless the context clearly dictates otherwise.

Thus, for example, the term “module” is intended to mean one or more modules or a combination of modules. Furthermore, as used herein, the term “based on” includes based at least in part on. Thus, a feature that is described as based on some cause, can be based only on that cause, or based on that cause and on one or more other causes.

It will be apparent that multiple embodiments of this disclosure may be practiced without some or all of these specific details. In other instances, well-known process operations have not been described in detail in order not to unnecessarily obscure the present embodiments. The following description of embodiments includes references to the accompanying drawing. The drawing shows illustrations in accordance with example embodiments.

These example embodiments, which are also referred to herein as “examples,” are described in enough detail to enable those skilled in the art to practice the present subject matter. The embodiments can be combined, other embodiments can be utilized, or structural, logical and operational changes can be made without departing from the scope of what is claimed. The following detailed description is, therefore, not to be taken in a limiting sense, and the scope is defined by the appended claims and their equivalents.

Alluding to the above, for purposes of this patent document, the terms “or” and “and” shall mean “and/or” unless stated otherwise or clearly intended otherwise by the context of their use. The term “a” shall mean “one or more” unless stated otherwise or where the use of “one or more” is clearly inappropriate. The terms “comprise,” “comprising,” “include,” and “including” are interchangeable and not intended to be limiting. For example, the term “including” shall be interpreted to mean “including, but not limited to.”

Accordingly, as used herein, terms such as “identifier of an object” and “memory address of an object” should be understood to refer to the identifier (e.g., memory address) itself or to a variable at which a value representing the identifier is stored. As used herein, the term “module” refers to a combination of hardware (e.g., a processor such as an integrated circuit or other circuitry) and software (e.g., machine-or processor-executable instructions, commands, or code such as firmware, programming, or object code). A combination of hardware and software includes hardware only (i.e., a hardware element with no software elements), software hosted at hardware (e.g., software that is stored at a memory and executed or interpreted at a processor), or at hardware and software hosted at hardware.

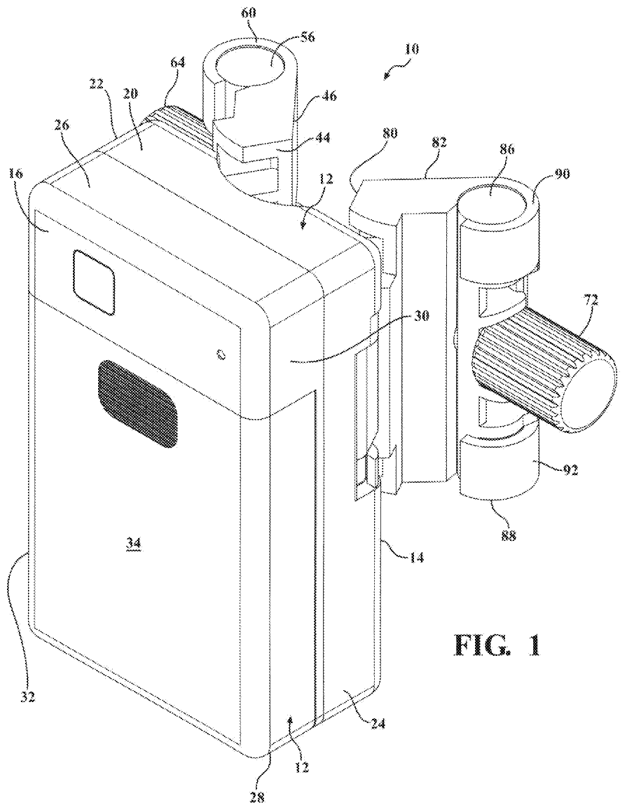

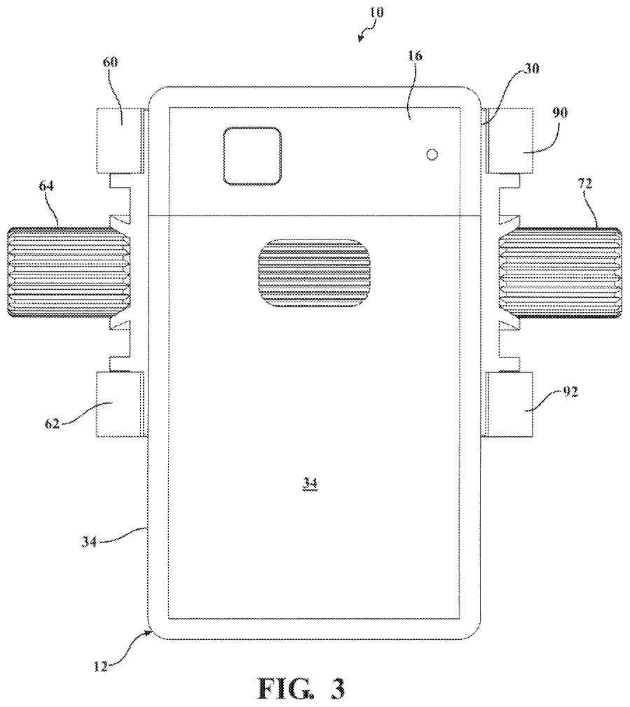

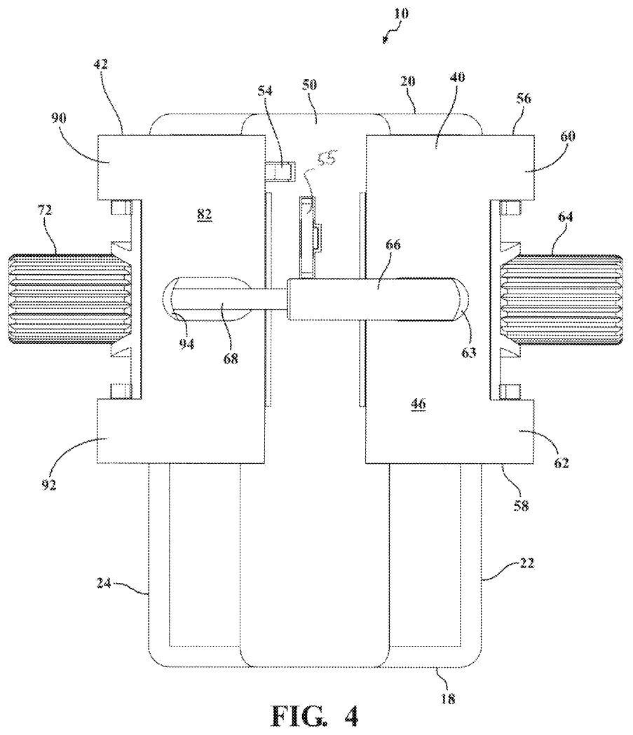

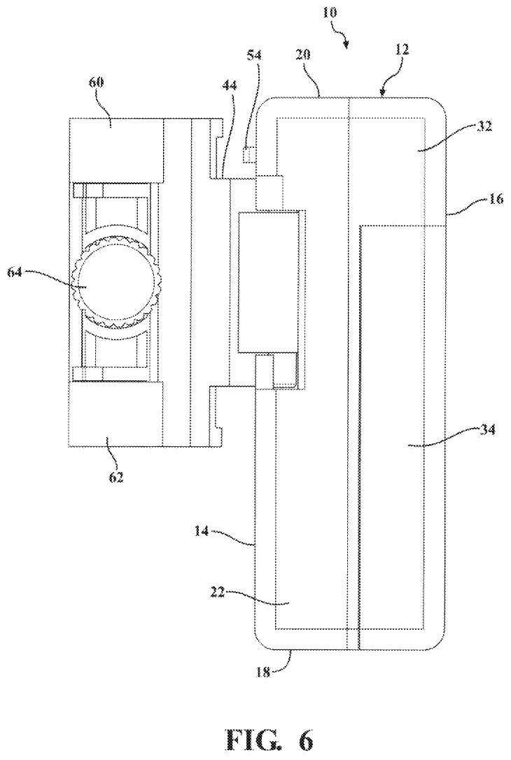

Referring now to the drawings and the illustrative embodiments depicted in FIGS. 1 through 7, a sensor device (the device) for non-invasive monitoring of energy consumption usage of the present invention is generally shown at 10. The device 10 includes a housing, generally indicated at 12 having a bottom part 14 and a top part 16. The bottom part 14 includes end sides 18, 20 and side walls 22, 24. The top part 16 includes end sides 26, 28 and side walls 30, 32. The top part 16 includes a cover 34 with slidably movable along the top part 16 and along the side walls 30, 32 to check, service, of replace internal hardware and software components located inside the housing 12. The housing 12 is formed from polymeric materials. Alternatively, it may be formed from non-polymeric materials without limiting the scope of the present invention.

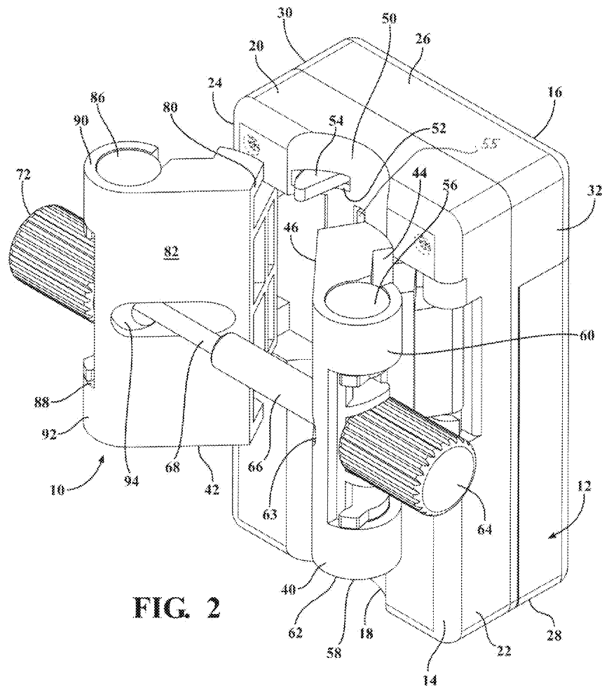

Referring back to FIG. 2, a first clamping element 40 is pivotably connected to the side wall 22 of the bottom part 14 includes a base 44 extending to a clamping surface 46 defining an angle of up to 90 degrees between the base 44 and the clamping surface 46. Those skilled in the art will appreciate that the base 44 extending to the clamping surface 46 may define an angle of at least 90 degrees between the base 44 and the clamping surface 46 without limiting the scope of the present invention. The clamping element 40 includes a flange portion 50 extending from the base 44. The flange portion 50 include an opening 52 to receive a sensing element 54 extending from the bottom part 14 to engage with the opening 52 when the device if secured to the power cable or any other surface without limiting the scope of the present invention. A sensor element 55 is used in the device 10 to read and determine magnetic fields information.

The clamping surface 46 includes side gripping elements 56, 58 semi-circled by respective ear layers 60, 62 and defining an inlet portion 63 therebetween to receive a first connector element presenting a grip portion 64, a female tubular member 66 to receive a male tubular member 68 of a second connector element 70 further defining a grip portion 72.

Referring back to FIG. 2, a second clamping element 42 is pivotably connected to the side wall 24 of the bottom part 14 includes a base 80 extending to a clamping surface 82 defining an angle of up to 90 degrees between the base 80 and the clamping surface 82. Those skilled in the art will appreciate that the base 80 extending to the clamping surface 82 may define an angle of at least 90 degrees between the base 80 and the clamping surface 82 without limiting the scope of the present invention.

The clamping surface 82 includes side gripping elements 86, 88 semi-circled by respective ear layers 90, 92 and defining an inlet portion 94 therebetween to receive the male tubular member 68 of the second connector element 70 further. The clamping elements 40, 42 are formed from polymeric materials. Alternatively, the clamping elements 40, 42 may be formed from non-polymeric materials without limiting the scope of the present invention.

As best shown in FIG. 2, the housing 12 includes a unique mounting mechanism formed by the clamping elements 40, 42 thereby allowing to attach the device 10 on any power cable that may have allows the sensor to be installed on power cables with different cross-sections including and not limited to a circular cross section and a non-circular cross section such as, rectangular, triangular or any other cross sections. To mount the device 10 on the power cable C, it is necessary to spread the clamping elements 40, 42 using the clamping mechanism to the distance required for installation.

After the clamping elements 40, 42 have sufficient distance therebetween to receive the power cable therebetween to install the cable, it must be placed between the fixing mechanism and clamped until the device 10 is firmly fixed on the power cable. To allow firm fixation, the first connector element presenting the grip portion 64 and the female tubular member 66 will receive the male tubular member 68 of the second connector element 70 thereby fixing the device 10 to the cable.

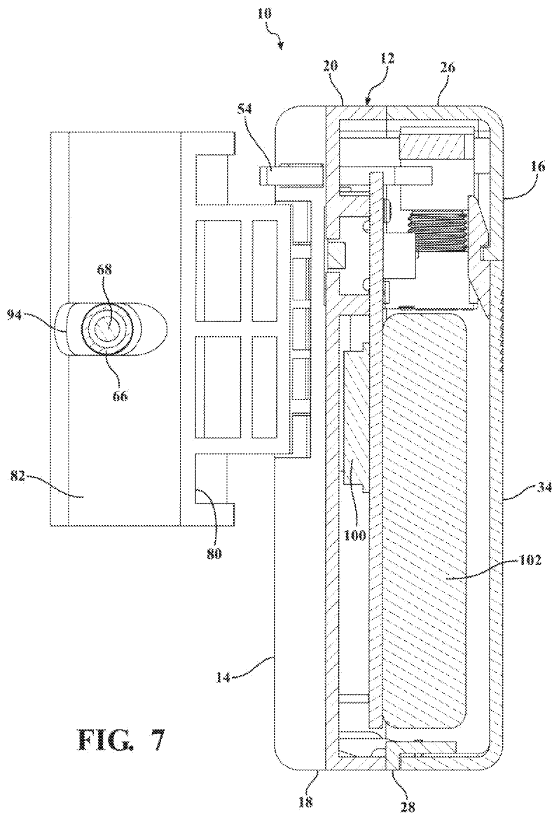

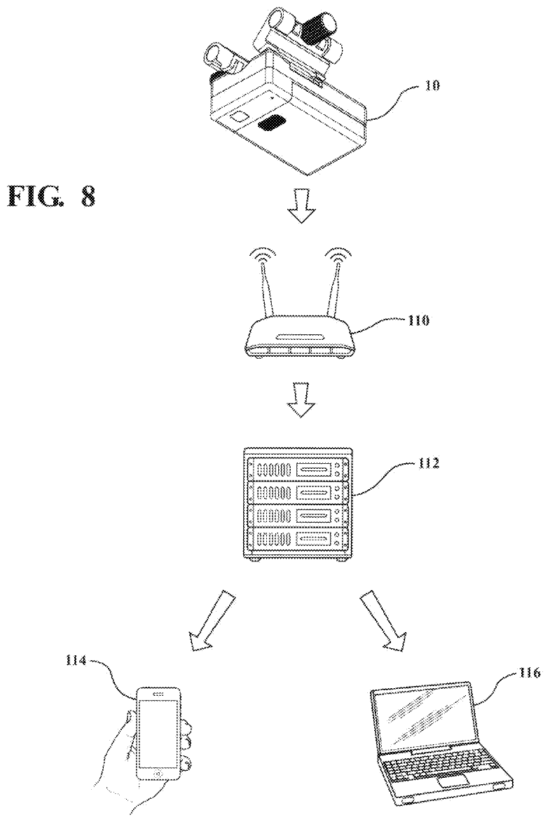

Referring now to FIGS. 7 and 8, the device includes a platform 100 having a hardware, a firmware, a software and a rechargeable battery 102 to ensures constant the operation of the device 10. The sensing element, also knows as a tongue 54 is configured to detect the cross-sectional dimensions and shape of the power cable C and send the data via wireless signal away from the location where the device 10 is connected to the power cable C. In certain embodiments, the device further includes an integrated wireless communication module disposed within the housing and operably connected to the controller. The communication module is configured to transmit sensed data collected by the sensing element to a remote computing system. The communication module may support one or more wireless communication technologies including, but not limited to, Wi-Fi, Bluetooth, ZigBee, LoRaWAN, cellular communication, or other wireless industrial communication protocols. The communication module may also receive configuration commands, calibration instructions, and firmware updates from the remote computing system.

Alluding to the above, the device 10 needs to be installed on the power cable C, paired to a mobile device (as described below) and calibrated on the power cable C prior to using mode. Pairing process starts in a mobile application and being guided through a wizard or instructions on the mobile application. Calibration mode is performed by following methods and steps. After the device 10 is mounted on the power cable C, device 10 needs to be turned on and also needs to be in an idle mode and slowly rotated around the power cable C for multiple turns until a firmware and a software find proper spot to secure it on the power cable C and provides feed back to an installer (not shown) by sound or any other methods, without limiting the scope of the present invention. After calibration is done, the device 10 sends data to the cloud and ready to use.

As best shown in FIG. 8, when the device 10 is installed on a surface such as the cable or any other surface, the device 10 receives data in form of magnetic field converted to electrical signal inside of the device from the cable and sends the data to a receiver/transmitter communication device 110. The receiver/transmitter communication device 110 is operably communicated with a server 112 that stores the information. The server 112 stores the information received that includes and is not limited to the cross-sectional dimensions and shape of the power cable as well as current being flowed in the cable to calculate consumption. The server 112 stores the data and processes the data. The system can be used via downloadable application on a mobile device 114 or via a personal computer 116.

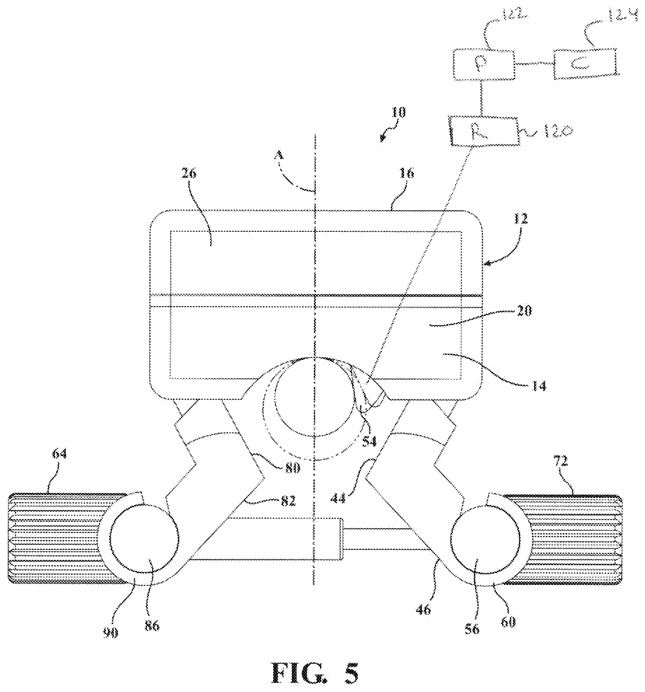

Referring back to FIG. 5, the sensing element 54 extending from the bottom part 14 to engage with the opening 52 when the device if secured to the power cable is moved to and away from the central axis and therefore to and from the cable, as shown in cross section, to determine diameter of the cable and send the information to a resistor device 120, which further translates the information about the diameter of the cable to a processor 122 and further to a controller device 124. In certain embodiments, the controller processor is configured to convert electromagnetic field measurements obtained by the sensing element into estimates of electrical current flowing through the monitored power cable. The processor may utilize signal processing algorithms and calibration parameters associated with the detected cable geometry to calculate electrical parameters including current, voltage estimation, power consumption, and cumulative energy usage. These calculated parameters may then be transmitted to the remote computing system for storage, analysis, and visualization.

A user needs to download the software application depending on the model of user's mobile phone from the corresponding application store. After installing the software application on the mobile phone, the user needs to register in the application indicating his registration data. Next, the user needs to create a location in the application to which the sensors will be bound.

After creating the location, the system will bind and configure the sensor in the system. Using the mobile application, the user scans the QR code printed on the device 10 or enter the ID of the device 10. The mobile application connects to the device 10 via the Wi-Fi network and performed calibration and pairing. After successful connection, the user receives a notification on the screen of the mobile phone. The user specifies the settings of his Wi-Fi network, to which the device 10 will subsequently have to c In another embodiment, the sensing element may include multiple sensing technologies operating simultaneously, including but not limited to: magnetic field sensors; Hall-effect sensors; Rogowski coil sensors; inductive current sensors; thermal sensors configured to measure cable temperature; and vibration sensors configured to detect operational characteristics of the monitored equipment.

In certain embodiments, the device may include a plurality of distributed sensor elements arranged circumferentially around the central axis of the housing to obtain more accurate readings of electromagnetic field distribution around the power cable.

The controller may include machine-learning algorithms configured to analyze power consumption patterns and automatically identify operational states of the monitored equipment including: idle state; startup state; peak operation state; abnormal energy consumption conditions. In certain embodiments, the device may perform local data processing prior to transmitting data to the remote computing system. The controller may execute embedded algorithms configured to preprocess sensor signals, filter noise, identify electrical load signatures, and determine operational characteristics of the monitored equipment. Such local processing may reduce communication bandwidth requirements and enable near real-time detection of abnormal operating conditions.

The device may further include a predictive maintenance module configured to detect anomalies in power consumption patterns and generate alerts indicating possible equipment malfunction.

In certain embodiments, the device may include a removable or replaceable battery pack and may further include energy harvesting circuitry configured to recharge the battery using electromagnetic energy from the monitored cable.

The device may further include a wireless communication module supporting multiple communication protocols, including but not limited to: Wi-Fi; Bluetooth; ZigBee; LoRaWAN; cellular communication; and industrial communication protocols.

In certain embodiments, the housing may include environmental protection features, including: water resistant seals; dust protection structures; thermal insulation layers.

The clamping elements may further include self-adjusting gripping surfaces configured to automatically adapt to cables of different diameters and shapes.

In certain embodiments, the device may include automatic cable recognition algorithms configured to determine cable type based on measured electromagnetic signatures.

The device may further include local data storage memory configured to store energy consumption data prior to transmission to the remote server.

In certain embodiments, the device may include a security module configured to encrypt transmitted data to prevent unauthorized access.

The device may further include a visual indicator or display module configured to indicate device status, calibration status, and communication status.

In certain embodiments, the device may be configured to monitor multiple adjacent power cables simultaneously.

The device may also be configured for use with non-electrical energy sources, including compressed air lines, hydraulic systems, or fluid conduits connect. In certain embodiments, multiple sensor devices may be deployed across a facility and may communicate with a centralized management platform configured to aggregate energy consumption data across multiple machines, production lines, or industrial processes. The centralized platform may generate facility-level energy analytics, optimization recommendations, and automated alerts relating to equipment performance and energy efficiency.

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A sensor device for non-invasive monitoring of electrical energy consumption in a power cable, comprising:
a housing having a bottom portion and a top portion defining an interior cavity and a central axis;
at least one sensing element disposed within the housing and configured to detect electromagnetic fields generated by electrical current flowing through a power cable;
a controller disposed within the housing and operably connected to the sensing element;
a pair of clamping elements pivotably mounted to the housing and configured to selectively move toward and away from the central axis to secure the housing to the power cable; and
a communication module configured to transmit sensed data to a remote computing system for analysis of energy consumption.

2. The sensor device of claim 1 wherein the sensing element comprises at least one of a magnetic field sensor, a Hall-effect sensor, an inductive current sensor, a Rogowski coil sensor.

3. The sensor device of claim 1 wherein the sensing element is configured to detect a cross-sectional dimension of the power cable.

4. The sensor device of claim 1 wherein the pair of clamping elements include gripping surfaces configured to engage cables having different cross-sectional shapes.

5. The sensor device of claim 1 wherein the housing includes a removable cover configured to allow access to electronic components located within the housing.

6. The sensor device of claim 1 further comprising a rechargeable battery disposed within the housing.

7. The sensor device of claim 6 further comprising an energy harvesting circuit configured to recharge the battery using electromagnetic energy generated by current flowing through the power cable.

8. The sensor device of claim 1 further comprising a plurality of sensing elements distributed circumferentially around the central axis.

9. The sensor device of claim 1 further comprising at least one environmental sensor selected from the group consisting of: temperature sensors; vibration sensors; acoustic sensors.

10. A system for monitoring electrical energy consumption of industrial equipment comprising:
a sensor device configured to be mounted on a power cable carrying electrical current to the industrial equipment;
a sensing element configured to detect electromagnetic fields generated by the electrical current;
a communication module configured to transmit sensor data;
a remote computing system configured to receive the sensor data and calculate electrical energy consumption of the industrial equipment.

11. The system of claim 10 wherein the remote computing system comprises a cloud-based server.

12. The system of claim 10 wherein the remote computing system includes a machine learning module configured to identify operational states of the monitored equipment.

13. The system of claim 12 wherein the operational states include idle state, startup state; peak operation state; abnormal operation state.

14. The system of claim 10 further comprising a mobile device executing a software application configured to display energy consumption data.

15. The system of claim 10 wherein the communication module supports at least one wireless protocol selected from: Wi-Fi; Bluetooth; Zigbee; LoRaWAN; cellular communication.

16. The system of claim 10 further comprising a predictive maintenance module configured to detect anomalies in energy consumption patterns.

17. The system of claim 10 further comprising a security module configured to encrypt transmitted data.

18. A method for monitoring electrical energy consumption of industrial equipment comprising:
mounting a sensor device on a power cable supplying electrical current to the equipment;
detecting electromagnetic field data generated by the current flowing through the cable;
converting the electromagnetic field data into electrical consumption measurements; and
transmitting the measurements to a remote computing system.

19. The method of claim 18 further comprising calibrating the sensor device by rotating the device around the power cable.

20. The method of claim 18 further comprising determining a diameter of the power cable using a sensing element movable toward and away from a central axis of the device.

21. The method of claim 18 further comprising transmitting energy consumption data to a cloud server.

22. The method of claim 18 further comprising analyzing energy consumption data using machine learning algorithms.

23. The method of claim 18 further comprising generating predictive maintenance alerts based on abnormal power consumption patterns.

24. The method of claim 18 further comprising storing energy consumption data in a local memory of the sensor device prior to transmission.

25. The method of claim 18 further comprising displaying energy consumption data on a mobile device.
